(19) United States
(12) Patent Application Publication
(10) Pub. No.: US 2010/0075066 A1
(43) Pub. Date: Mar. 25, 2010

(54) PLASMA FILM FORMING APPARATUS AND PLASMA FILM FORMING METHOD

(75) Inventors: Hirokazu Ueda, Hyogo (JP); Masahiro Horigome, Yamanashi (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/444,600

(22) PCT Filed: Sep. 11, 2007
(86) PCT No.: PCT/JP2007/067657

§ 371 Date: Apr. 7, 2009

(30) Foreign Application Priority Data
Oct. 16, 2006 (JP) 2006-281286
May 22, 2007 (JP) 2007-135965

(51) Int. Cl. C23C 16/511; C23C 16/00

(52) U.S. Cl. 427/575; 118/723 AN

(57) ABSTRACT

A plasma film forming apparatus includes: a processing chamber; a mounting table for mounting thereon a target object; a ceiling plate which is installed at a ceiling portion and is made of a dielectric material; a gas introduction mechanism for introducing a processing gas including a film formation source gas and a supporting gas; and a microwave introduction mechanism which is installed at a ceiling plate's side and has a planar antenna member. The gas introduction mechanism includes: a central gas injection hole for the source gas, located above a central portion of the target object; and a plurality of peripheral gas injection holes for the source gas, arranged above a peripheral portion of the target object along a circumferential direction thereof. A plasma shielding member is installed above the target object and between the central gas injection hole and the peripheral gas injection holes along the circumferential direction thereof.

### TECHNICAL FIELD

The present invention relates to a plasma film forming apparatus and a plasma film forming method for forming a thin film by allowing plasma generated by microwaves to act on a semiconductor wafer or the like.

### BACKGROUND ART

Along with a recent trend of high densification and high miniaturization of semiconductor products, a plasma processing apparatus has been used for performing various processes such as film formation, etching, asking and the like in a semiconductor manufacturing process. Specifically, since plasma can be generated stably even under a high vacuum condition at a relatively low pressure in the range of, e.g., about 0.1 mTorr (13.3 mPa) to several Torr (several hundreds of Pa), a microwave plasma apparatus for generating a high-density plasma by using microwaves tends to be used. Such plasma processing apparatus is disclosed in, for example, Patent Documents 1 to 5. Herein, a typical plasma film forming apparatus using microwaves to form a thin film on a semiconductor wafer will be described schematically with reference to FIGS. 11 to 13. FIG. 11 presents a schematic configuration diagram illustrating a typical plasma film forming apparatus in accordance with the prior art, and FIG. 12 is a plane bottom view of a gas introduction mechanism.

As illustrated in FIG. 11, a plasma film forming apparatus 2 includes an evacuable processing chamber 4 and a mounting table 6 disposed in the processing chamber 4 for mounting a semiconductor wafer W thereon. Further, airtightly provided in a ceiling portion facing the mounting table 6 is a disc-shaped ceiling plate 8 made of a microwave transmissive material such as alumina, aluminum nitride, quartz, or the like. Further, provided in a sidewall of the processing chamber 4 are a gas introduction mechanism 10 for introducing a gas into the processing chamber 4 and an opening 12 for loading and unloading the wafer W. A gate valve G for airtightly opening and closing the opening 12 is installed at the opening 12. Further, a gas exhaust port 14 is provided in a bottom portion of the processing chamber 4 and connected to an exhaust system (not shown). With this configuration, the inside of the processing chamber 4 can be evacuated as mentioned above.

Further, on the upper side of the ceiling plate 8, there is installed a microwave introduction mechanism 16 for introducing microwaves into the processing chamber 4. To be specific, the microwave introduction mechanism 16 includes a disc-shaped planar antenna member 18 made of, e.g., a copper plate having a thickness of several mm on the top surface of the ceiling plate 8 and a wavelength shortening member 20 made of, e.g., a dielectric material, for shortening a wavelength of the microwave on the planar antenna member 18. The planar antenna member 18 is provided with a plurality of microwave radiation slots 22 formed of through holes having, for example, an elongated groove shape.

A central conductor 24A of a coaxial waveguide 24 is connected to the planar antenna member 18, and an external conductor 24B of the coaxial waveguide 24 is connected with a central portion of a waveguide box 26 which encloses the entire wavelength shortening member 20. Therefore, microwaves of, e.g., 2.45 GHz, generated by a microwave generator 28 can be guided to the planar antenna member 18 or the wavelength shortening member 20 after being converted to a predetermined oscillation mode by a mode converter 30. The microwaves propagate along a radial direction of the antenna member 18 in a radial shape. Then, the microwaves are emitted from the respective slots 22 provided in the planar antenna member 18, and are transmitted through the ceiling plate 8. Thereafter, the microwaves are introduced into the processing chamber 4, and by these microwaves, plasma is generated in a processing space S of the processing chamber 4, whereby a film forming process is performed on the semiconductor wafer W. Further, on the top surface of the waveguide box 26, there is installed a cooling unit 32 for cooling the wavelength shortening member 20 heated by dielectric loss of the microwaves.

Furthermore, the gas introduction mechanism 10 has a shower head unit 34 formed of, e.g., a quartz tube having, e.g., a lattice pattern as illustrated in FIG. 12 so as to supply a source gas to the whole area of the processing space S within the processing chamber 4. A plurality of gas injection holes 34A is formed throughout the substantially entire bottom surface of the shower head unit 34 and the source gas is injected from each of the gas injection holes 34A. Further, the gas introduction mechanism 10 has a gas nozzle 36 made of, e.g., a quartz tube so as to introduce other supporting gases.

In addition, as shown in a schematic diagram of Fig. which illustrates another example of the conventional plasma film forming apparatus, a circular ring-shaped gas ring 38 is installed at a sidewall of a processing chamber directly under a ceiling plate 8 instead of the gas nozzle 36 of FIG. 11. Gas injection holes 38A are formed in the gas ring 38 along a circumferential direction thereof at a predetermined distance maintained therebetween, and an O₂ gas or an Ar gas is supplied through these respective gas injection holes 38A. In this case, TEOS (Tetra-Ethyl-Ortho-Silicate) as a source gas is supplied from a shower head unit 34, as in the case illustrated in FIG. 11.

Patent Document 1: Japanese Patent Laid-open Publication No. H3-191073

Patent Document 2: Japanese Patent Laid-open Publication No. H5-343334

Patent Document 3: Japanese Patent Laid-open Publication No. H9-181052

Patent Document 4: Japanese Patent Laid-open Publication No. 2003-332326

Patent Document 5: Japanese Patent Laid-open Publication No. 2006-128529

However, in case of forming a thin film such as a CF film having a relatively low binding energy by using a plasma CVD (Chemical Vapor Deposition) in the plasma film forming apparatus as illustrated above, less charge-up damage has occurred, and it has been possible to obtain sufficiently high film forming rate and high in-plane uniformity of film thickness. Thus, no critical problem has been accompanied. Meanwhile, in case of forming a thin film such as a SiO₂ film having a relatively high binding energy by using the plasma CVD, there have been problems that the film forming rate is considerably reduced and the in-plane uniformity of film thickness is deteriorated.

To be more specific, when forming the SiO₂ film by using the plasma CVD, a TEOS (Tetra-Ethyl-Ortho-Silicate) is used as a source gas, and an O₂ gas as an oxidizing gas and an Ar gas for stabilizing plasma are used as supporting gases, for example. Further, as illustrated in FIG. 11 and FIG. 12, the TEOS gas, which is used as the source gas and has a very small supply amount in comparison with the supporting gases, is flown into the shower head unit 34 and is introduced into the processing space S from the respective gas injection holes 34A substantially in a uniform manner. Meanwhile, the O₂ gas or the Ar gas having a greater supply amount than that of the TEOS is introduced from the gas nozzle 36. Further, in the apparatus example shown in FIG. 13, the O₂ gas or the Ar gas is supplied from the gas ring 38.

In such case, however, since the binding energy of SiO₂ is great as stated above, there occur problems that the film forming rate is reduced greatly and the in-plane uniformity of film thickness is deteriorated. It is deemed that such problems are caused because the shower head unit is formed in the lattice shape. That is, since the lattice portion formed over the entire horizontal plane of the processing space S has a plasma shielding function, the plasma is blocked by the lattice portion, resulting in a failure to obtain sufficient energy for forming the SiO₂. Though various attempts have been made to modify the shape of the gas introduction mechanism 10, a satisfactory result is yet to be obtained.

### DISCLOSURE OF THE INVENTION

In view of the foregoing, the present invention is conceived to efficiently solve the above-mentioned problems. An object of the present invention is to provide a plasma film forming apparatus and a plasma film forming method, capable of maintaining a high film forming rate and a high in-plane uniformity of film thickness.

The present invention provides a plasma film forming apparatus including: a processing chamber which has its ceiling portion opened and is evacuable; a mounting table installed in the processing chamber, for mounting thereon a target object to be processed; a ceiling plate which is airtightly installed at an opening of the ceiling portion and is made of a dielectric material capable of transmitting a microwave; a gas introduction mechanism for introducing a processing gas including a film formation source gas and a supporting gas into the processing chamber; and a microwave introduction mechanism which is installed at a ceiling plate's side and has a planar antenna member so as to introduce the microwave into the processing chamber, wherein the gas introduction mechanism includes: a central gas injection hole for the source gas, located above a central portion of the target object; a plurality of peripheral gas injection holes for the source gas, arranged above a peripheral portion of the target object along a circumferential direction of the target object; and a plasma shielding member for shielding plasma is installed above an intermediate portion located between the central portion and the peripheral portion of the target object along the circumferential direction thereof.

As stated above, the central gas injection hole is installed above the central portion of the target object, and the peripheral gas injection holes are installed above the peripheral portion thereof, and the plasma shielding member is installed above the intermediate portion located between the central portion and the peripheral portion of the target object along the circumferential direction thereof, so that the plasma is shielded by the plasma shielding member. Accordingly, a decrease of the electron density of plasma can be prevented by minimizing the area occupied by the gas introduction mechanism having the plasma shielding function. Further, the plasma at the intermediate portion of the target object where the film thickness tends to be thicker than other portions of the target object can be actively suppressed. As a result, the film forming rate and the in-plane uniformity of film thickness can be maintained high.

The present invention provides the plasma film forming apparatus, wherein the plasma shielding member is located above a position where a thin film formed on a surface of the target object becomes thicker when a film formation is performed without the plasma shielding member by injecting the source gas from the central gas injection hole and the peripheral gas injection holes.

The present invention provides the plasma film forming apparatus, wherein the plasma shielding member includes one or more ring member.

The present invention provides the plasma film forming apparatus, wherein the plasma shielding member is made of one material selected from a group consisting of quartz, ceramic, aluminum and semiconductor.

The present invention provides the plasma film forming apparatus, wherein the gas introduction mechanism includes a central gas nozzle unit having the central gas injection hole and a peripheral gas nozzle unit having the peripheral gas injection holes.

The present invention provides the plasma film forming apparatus, wherein both the central gas nozzle unit and the peripheral gas nozzle unit have a ring shape.

The present invention provides the plasma film forming apparatus, wherein the central gas nozzle unit and the peripheral gas nozzle unit are configured such that their gas flow rates are individually controlled.

The present invention provides the plasma film forming apparatus, wherein the gas introduction mechanism includes a supporting gas nozzle unit for introducing the supporting gas.

The present invention provides the plasma film forming apparatus, wherein the supporting gas nozzle unit has a gas injection hole for the supporting gas, which injects the gas toward the ceiling plate from a position directly under a central portion of the ceiling plate.

The present invention provides the plasma film forming apparatus, wherein the gas introduction mechanism includes a supporting gas supply unit installed at the ceiling plate so as to introduce the supporting gas.

The present invention provides the plasma film forming apparatus, wherein the supporting gas supply unit has a gas passage for the supporting gas installed at the ceiling plate, and a plurality of gas injection holes for the supporting gas installed at a bottom surface of the ceiling plate so as to communicate with the gas passage.

The present invention provides the plasma film forming apparatus, wherein the gas injection holes are distributed throughout the bottom surface of the ceiling plate.

The present invention provides the plasma film forming apparatus, wherein the gas passage for the supporting gas and/or the gas injection holes for the supporting gas are filled with a porous dielectric material having a gas permeable property.

The present invention provides the plasma film forming apparatus, wherein an introduction amount of the source gas is in a range of about 0.331 sccm/cm² to 0.522 sccm/cm².

The present invention provides the plasma film forming apparatus, wherein the gas injection holes for the source gas are arranged on the same horizontal plane, and a distance between the mounting table and the horizontal plane on which the gas injection holes for the source gas are located is set to be about 40 mm or more.

The present invention provides the plasma film forming apparatus, wherein the mounting table has a heating unit for heating the target object.

The present invention provides the plasma film forming apparatus, wherein the source gas includes one material selected from a group consisting of TEOS, SiH₄ and Si₂H₆, and the supporting gas includes one material selected from a group consisting of O₂, NO, NO₂, N₂O and O₃.

The present invention provides a plasma film forming method including: introducing a processing gas including a film formation source gas and a supporting gas into an evacuable processing chamber; and generating plasma by introducing a microwave from a ceiling of the processing chamber and forming a thin film on a surface of a target object installed in the processing chamber, wherein, when the processing gas is introduced into the processing chamber, the source gas is injected and introduced from above a central portion and a peripheral portion of the target object, and the plasma is shielded by a plasma shielding member installed above the target object at a position between the central portion and the peripheral portion of the target object, so that the thin film is formed.

According to the plasma film forming apparatus and the plasma film forming method in accordance with the present invention, it is possible to obtain advantageous effects as stated below. The central gas injection hole is installed above the central portion of the target object, and the peripheral gas injection holes are installed above the peripheral portion thereof, and the plasma shielding member is installed above the intermediate portion located between the central portion and the peripheral portion of the target object along the circumferential direction thereof, so that the plasma is shielded at a place of the plasma shielding member. Accordingly, a decrease of the plasma density can be prevented by minimizing the area occupied by the gas introduction mechanism having the plasma shielding function. Further, the plasma at the intermediate portion of the target object where the film thickness tends to be thicker than other portions of the target object can be actively suppressed. As a result, the film forming rate and the in-plane uniformity of film thickness can be maintained high.

### BRIEF DESCRIPTION OF THE DRAWINGS

FIG. 1 is a configuration view of a first embodiment of a plasma film forming apparatus in accordance with the present invention;

FIG. 2 is a plane bottom view of a gas introduction mechanism;

FIG. 3 is a graph for evaluating an effect of a lattice-shaped shower head unit upon a film forming rate;

FIGS. 4(A and B) provides schematic diagrams showing a relationship between a position of each gas injection hole and a film thickness along a cross-sectional direction of a wafer so as to explain a principle how a plasma shielding member contributes to the improvement of an in-plane uniformity of film thickness;

FIGS. 5(A and B) presents diagrams showing simulation results of film thickness distribution to explain an effect of the plasma shielding member;

FIGS. 6(A and B) offers graphs showing a relationship between a position along a diametric direction of the wafer and a film forming rate;

FIG. 7 is a schematic configuration view of a second embodiment of a plasma film forming apparatus in accordance with the present invention;

FIGS. 8(A and B) provides plane views showing a part of a ceiling plate in accordance with the second embodiment;

FIG. 9 is a graph showing dependency of a film forming rate and an in-plane uniformity of film thickness upon a TEOS flow rate;

FIG. 10 is a graph showing dependency of a film forming rate and an in-plane uniformity of film thickness upon a distance between a mounting table and a horizontal level on which gas injection nozzles for TEOS are positioned;

FIG. 11 is a schematic configuration view of a typical conventional plasma film forming apparatus;

FIG. 12 is a plane bottom view of a gas introduction mechanism; and

FIG. 13 is a schematic view showing another example of the conventional plasma film forming apparatus.

### BEST MODE FOR CARRYING OUT THE INVENTION

Hereinafter, embodiments of a plasma film forming apparatus and a plasma film forming method in accordance with the present invention will be described in detail with reference to the accompanying drawings.

### First Embodiment

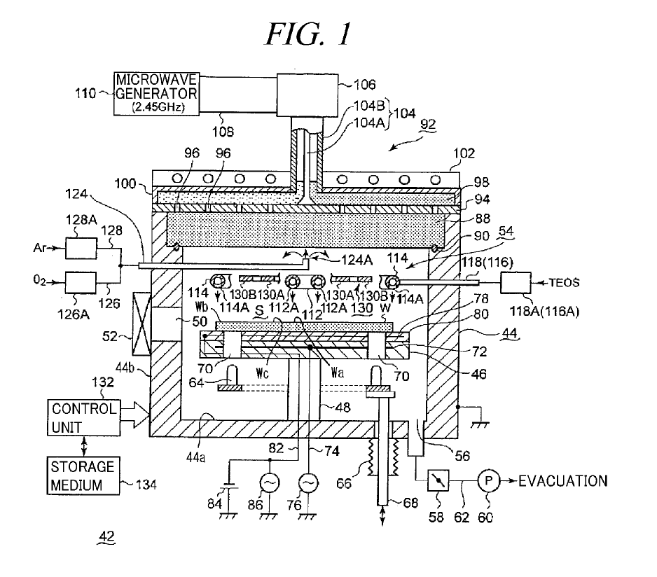

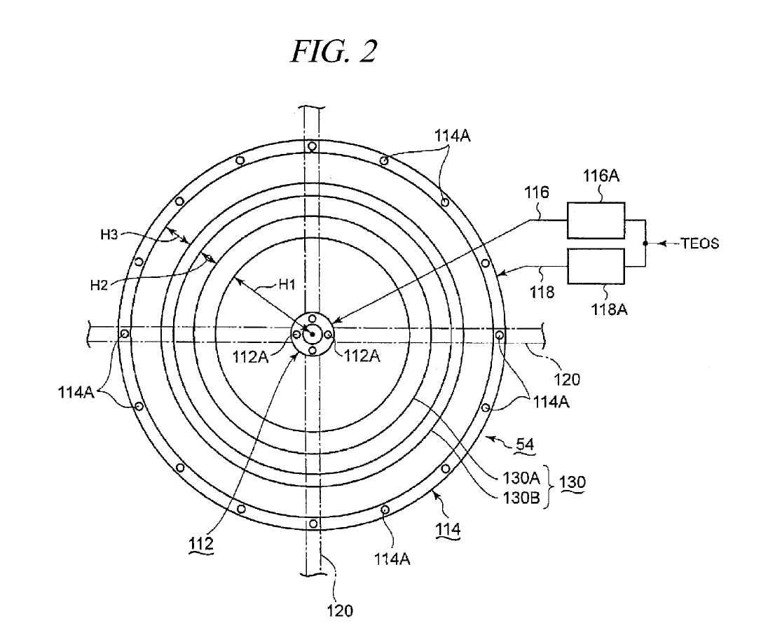

FIG. 1 is a configuration view of a first embodiment of a plasma film forming apparatus in accordance with the present invention, and FIG. 2 is a plane bottom view of a gas introduction mechanism. Here, description will be provided for an example case of forming a thin film made of SiO₂ by a plasma CVD by using TEOS as a source gas while using an O₂ gas serving as an oxidizing gas and an Ar gas for stabilizing plasma as supporting gases. Further, it may be possible to add a rare gas such as an Ar gas to the TEOS if necessary.

As illustrated, a plasma film forming apparatus 42 includes a cylindrical processing chamber 44 of which sidewall and bottom portion is made of, for example, a conductor such as aluminum or the like, and the inside of the processing chamber 44 is configured as a hermetically sealed processing space S having, for example, a circular shape, wherein plasma is generated in the processing space S. The processing chamber 44 is grounded.

Disposed in the processing chamber 44 is a mounting table 46 for mounting a target object to be processed, e.g., a semiconductor wafer W on the top surface thereof. The mounting table 46 is made of, e.g., alumite-treated aluminum or the like and formed in a substantially flat circular plate shape. The mounting table 46 is installed upright from a bottom portion 44a of the chamber 44 via a supporting column 48 made of, e.g., aluminum or the like. Installed at a sidewall 44b of the processing chamber 44 is a loading/unloading port 50 used for loading and unloading the wafer W to and from the inside of the processing chamber 44, and installed at the loading/unloading port 50 is a gate valve 52 for airtightly opening and closing the loading/unloading port 50.

Furthermore, installed in the processing chamber 44 is a gas introduction mechanism 54 for introducing various kinds of gases into the processing chamber 44. The detailed configuration of this gas introduction mechanism 54 will be described later. Furthermore, at the bottom portion 44a of the processing chamber 44, there is provided a gas exhaust port 56. The gas exhaust port 56 is connected with a gas exhaust path 62 in which a pressure control valve 58 and a vacuum pump 60 are installed in sequence, and the inside of the processing chamber 44 can be evacuated to a specific pressure level when necessary.

Furthermore, provided under the mounting table 46 are plural, e.g., three elevating pins 64 (only two are illustrated in FIG. 1) for moving the wafer W up and down while the wafer W is loaded or unloaded. The elevating pins 64 are moved up and down by an elevation rod 68 which is installed to penetrate the bottom portion of the chamber via an extensible/contractible bellows 66. Further, provided in the mounting table 46 are pin insertion holes 70 for allowing the elevating pins 64 to be inserted therethrough. The entire mounting table 46 is made of a heat resistant material, for example, ceramic such as alumina or the like, and a heating element 72 is embedded in the ceramic. The heating element 72 is formed of, e.g., a thin plate-shaped resistance heater buried in almost the entire area of the mounting table 46 and is connected to a heater power supply 76 via a wiring 74 which is extended through the inside of the supporting column 48. Further, it may be possible not to install the heating element 72.

Furthermore, provided on the top surface of the mounting table 46 is a thin electrostatic chuck 80 in which a conductor line 78 is embedded in, e.g., a mesh shape. The wafer W placed on the mounting table 46, specifically, on the electrostatic chuck 80 is attracted to and held on the electrostatic chuck 80 by an electrostatic attracting force. The conductor line 78 of the electrostatic chuck 80 is connected to a DC power supply 84 via a wiring 82 to exert the electrostatic attracting force. Further, the wiring 82 is connected to a high frequency bias power supply 86 for applying a high frequency bias power of, e.g., about 13.56 MHz to the conductor line 78 of the electrostatic chuck 80 when necessary. Further, depending on the types of processes, the high frequency bias power supply 86 may not be provided.

Further, a ceiling portion of the processing chamber 44 is opened, and a microwave transmissive ceiling plate 88 made of a dielectric material such as quartz or ceramic, e.g., alumina (Al₂O₃) or aluminum nitride (AlN) is installed airtightly at the ceiling portion via a sealing member 90 such as an O ring. The thickness of the ceiling plate 88 is set to be, e.g., about 20 mm in consideration of its pressure resistance.

Further, installed on the top surface side of the ceiling plate 88 is a microwave introduction mechanism 92. To be specific, the microwave introduction mechanism 92 is installed on the top surface of the ceiling plate 88, and includes a planar antenna member 94 for introducing microwaves into the processing chamber 44. In case of using a wafer having a size of about 300 mm, the planar antenna member 94 is made of a conductive material such as a silver-coated copper plate or aluminum plate having a diameter of about 400 to 500 mm and a thickness of about 1 to several mm, for example. This circular plate is provided with a plurality of microwave radiation slots 96 formed of through holes having, for example, an elongated groove shape. The arrangement pattern of the slots 96 is not particularly limited. For instance, they can be arranged in a concentric, spiral or radial pattern or can be uniformly distributed over the entire surface of the antenna member. The planar antenna member 94 has an antenna structure of a so-called RLSA (Radial Line Slot Antenna) type, which makes it possible to obtain high-density plasma with low electron temperature.

Furthermore, a flat plate-shaped wavelength shortening member 98 made of a dielectric material such as quartz or ceramic, e.g., alumina or aluminum nitride is installed on the planar antenna member 94, and the wavelength shortening member 98 has a high-k property to shorten the wavelength of the microwave. The wavelength shortening member 98 is formed in a thin circular plate shape and is installed substantially over the entire top surface of the planar antenna member 94.

Further, a waveguide box 100 configured as a hollow cylindrical shaped vessel made of a conductive material is installed to enclose the entire top surface and side surface of the wavelength shortening member 98. The planar antenna member 94 serves as a bottom plate of the waveguide box 100. Provided on the top surface of the waveguide box 100 is a cooling jacket 102 for cooling the waveguide box 100 by flowing a coolant.

The peripheral portions of the waveguide box 100 and the planar antenna member 94 are electrically connected with the processing chamber 44. Further, the planar antenna member 94 is connected with a coaxial waveguide 104. Specifically, the coaxial waveguide 104 includes a central conductor 104A; and an outer conductor 104B having a circular cross section and spaced apart from the central conductor 104A at the periphery thereof by a predetermined distance. The outer conductor 104B having the circular cross section is connected to the center of the top portion of the waveguide box 100, and the central conductor 104A is connected to the center portion of the planar antenna member 94 through the center of the wavelength shortening member 98.

Furthermore, the coaxial waveguide 104 is connected to a microwave generator 110 for generating microwaves of, e.g., about 2.45 GHz via a mode converter 106 and a rectangular waveguide 108 having a matching unit (not shown), and serves to propagate the microwaves to the planar antenna member 94 or the wavelength shortening member 98. The frequency of the microwaves is not limited to about 2.45 GHz and it is possible to use another level of frequency, e.g., about 8.35 GHz.

Hereinafter, there will be explained the gas introduction mechanism 54 for introducing the various kinds of gases into the processing chamber 44. The gas introduction mechanism 54 includes central gas injection holes 112A for the source gas which are positioned above a central portion Wa of the wafer W; and peripheral gas injection holes 114A for the source gas which are arranged above a peripheral portion Wb of the wafer W along its circumferential direction. To be more specific, the gas introduction mechanism 54 includes, as illustrated in FIG. 2, a circular ring-shaped central gas nozzle unit 112 having a small diameter and positioned above the central portion of the wafer W, and a circular ring-shaped peripheral gas nozzle unit 114 having approximately the same diameter as that of the wafer W and positioned above the peripheral portion (edge portion) of the wafer W.

Both the central gas nozzle unit 112 and the peripheral gas nozzle unit 114 are made of a ring-shaped quartz tube having an outer diameter of, e.g., about 5 mm. At the bottom surface of the central gas nozzle unit 112, the plural central gas injection holes 112A are arranged at a predetermined pitch along the circumferential direction thereof to inject the TEOS gas as the source gas downward toward the central portion Wa of the surface of the wafer W. Further, it may be also possible to form the central gas nozzle unit 112 with a quartz tube having a simple straight line shape instead of a ring shape and to provide a single central gas injection hole 112A by bending its leading end portion downward.

Further, at the bottom surface of the peripheral gas nozzle unit 114, the multiple peripheral gas injection holes 114A are arranged at a preset pitch along the circumferential direction thereof to inject the TEOS gas downward toward the peripheral portion (edge portion) Wb of the surface of the wafer W. The number of the peripheral gas injection holes 114A varies depending on the diameter of the wafer W. For example, if the diameter of the wafer W is about 300 mm, about 64 peripheral gas injection holes 114A are provided.

The central gas nozzle unit 112 and the peripheral gas nozzle unit 114 are connected with gas passages 116 and 118 whose internal portions of the processing chamber 44 are made of, for example, quartz tubes, respectively. Each of these gas passages 116 and 118 is installed to penetrate the sidewall of the processing chamber 44, and flow rate controllers 116A and 118A such as mass flow controllers are installed in the gas passages 116 and 118, respectively, so as to supply the TEOS while controlling their flow rates individually. A rare gas such as an Ar gas or the like can be added to the TEOS as a carrier gas, if necessary.

Further, instead of controlling the flow rates of the TEOS individually, it may be possible to supply the TEOS gas at a constant flow rate ratio to the central gas nozzle unit 112 and the peripheral gas nozzle unit 114.

Furthermore, the central gas nozzle unit 112 and the peripheral gas nozzle unit 114 are supported at the sidewall 44b of the processing chamber 44 by narrow support rods 120 installed in a cross shape, as illustrated by a dashed dotted line in the processing space S of FIG. 2. Further, the illustration of the support rods 120 is omitted in FIG. 1. Besides, it may be possible to form the support rods 120 with, for example, quartz tubes so as to use them also as the gas passages 116 and 118.

Further, the gas introduction mechanism 54 includes a supporting gas nozzle unit 124 (see FIG. 1) for introducing the supporting gas into the processing chamber 44. The illustration of the supporting gas nozzle unit 124 is omitted in FIG. 2. This supporting gas nozzle unit 124 is made of, e.g., a quartz tube installed to penetrate the sidewall 44b of the processing chamber 44 and is provided with a supporting gas injection hole 124A at a leading end portion thereof. The gas injection hole 124A is positioned above the central portion of the wafer W and directly below the ceiling plate 88, and it injects the gas upward toward the bottom surface of the ceiling plate 88.

Here, as the supporting gas, an O₂ gas serving as an oxidizing gas and an Ar gas for stabilizing the plasma are used. Flow rate controllers 126A and 128A such as mass flow controllers are installed in gas channels 126 and 128 for these gases, respectively, so that the O₂ gas and the Ar gas are supplied while their flow rates are controlled individually. Further, it may be also possible to install plural supporting gas nozzle units 124 so as to supply the O₂ gas and the Ar gas individually through separate routes.

In the processing space S, there is installed a plasma shielding member 130 for shielding the plasma, which is an inventive feature of the present invention. The plasma shielding member 130 is installed above an intermediate portion (also referred to as an intermediate circumferential portion) Wc positioned between the central portion and the peripheral portion of the wafer W along its circumferential direction so as to shield the plasma. Here, the intermediate circumferential portion Wc refers to a region between the central portion Wa and the peripheral portion Wb of the wafer W. To be specific, the plasma shielding member 130 is disposed above a position where a thin film (SiO₂) formed on the surface of the wafer W becomes relatively thick, if the film forming process is performed on the wafer W without the plasma shielding member 130 by injecting the source gas through each of the central gas injection holes 112A and the peripheral gas injection holes 114A.

Further, the O₂ gas and the Ar gas are also supplied from the supporting gas injection hole 124A during this film forming process. That is, in-plane uniformity of film thickness can be maintained high by selectively shielding some of the plasma at a position where the film thickness becomes thicker while minimizing the area occupied by the gas nozzle units having a plasma shielding function on the horizontal plane where the gas nozzle units are located in order to maintain a high film forming rate.

In the present embodiment, the plasma shielding member 130 is installed to be positioned above the substantially middle position between the center and the edge of the wafer W, or above a position slightly deviated outward from the middle position in a radial direction. Further, the plasma shielding member 130, the central gas nozzle unit 112 and the peripheral gas nozzle unit 114 are arranged on the substantially same horizontal plane (on the substantially same horizontal level). Furthermore, the central gas injection holes 112A and the peripheral gas injection holes 114A are also arranged on the substantially same horizontal plane (on the substantially same horizontal level). To be specific, the plasma shielding member 130 includes an inner ring member 130A having an annular shape (ring shape) and an outer ring member 130B disposed concentrically with the inner ring member 130A. Both ring members 130A and 130B are made of, for example, ring-shaped quartz plates. The width of the inner ring member 130A is about 10 mm and the thickness thereof is about 3 mm. The width of the outer ring member 130B is about 4 mm and the thickness thereof is about 3 mm.

Further, in case that the wafer W has a diameter of 300 mm, a distance H1 between the center of the processing space S and the inner ring member 130A is about 5.4 cm; a distance H2 between the inner ring member 130A and the outer ring member 130B is about 2.8 cm; and a distance H3 between the outer ring member 130B and the peripheral gas nozzle unit 114 is about 1.8 cm. Furthermore, the inner and outer ring members 130A and 130B are supported and fixed by the support rods 120 indicated by the dashed dotted line in FIG. 2. Here, though the plasma shielding member 130 is made up of the inner and outer ring members 130A and 130B which are divided into two parts in a concentric shape, it may be also possible to provide a single ring member by integrating them.

Referring back to FIG. 1, the whole operation of the plasma film forming apparatus 42 having the above-described configuration is controlled by a control unit 132 including, for example, a computer or the like, and a computer program for performing this operation is stored in a storage medium 134 such as a flexible disc, a CD (Compact Disc), a flash memory or the like. To be specific, according to instructions from the control unit 132, a control of supply or flow rates of each gas, a control of supply or power of microwaves or high frequency waves, a control of process temperature or process pressure, and so forth are performed.

Hereinafter, an example film forming method, which is performed by using the plasma film forming apparatus 42 having the above-described configuration, will be explained.

First, after the gate valve 52 is opened, the semiconductor wafer W is transferred into the processing chamber 44 by a transfer arm (not shown) through the loading/unloading port 50. Then, the wafer W is mounted on a mounting surface of the top surface of the mounting table 46 by moving the elevating pins 64 up and down, and the wafer W is electrostatically attracted by the electrostatic chuck 80. The wafer W is maintained at a specific process temperature by the heating element 72 if necessary. While controlling the flow rates of various kinds of gases supplied from a non-illustrated gas source, the gases are supplied into the processing chamber 44 through the gas introduction mechanism 54, and by controlling the pressure control valve 58, the inside the processing chamber 44 is maintained at a specific process pressure level.

At the same time, the microwave generator 110 of the microwave introduction mechanism 92 is operated, whereby the microwaves generated from the microwave generator 110 are supplied to the planar antenna member 94 and the wavelength shortening member 98 via the rectangular waveguide 108 and the coaxial waveguide 104. The microwaves whose wavelength is shortened by the wavelength shortening member 98 are radiated downward through each slot 96 and then generate plasma right below the ceiling plate 88 after passing through the ceiling plate 88. The plasma is diffused into the processing space S, so that a predetermined plasma CVD process is performed.

Here, the TEOS is supplied downward toward the processing space S from each of the central gas injection holes 112A of the central gas nozzle unit 112 and each of the peripheral gas injection holes 114A of the peripheral gas nozzle unit 114 constituting a part of the gas introduction mechanism 54, while its flow rates are individually controlled, and it is diffused into the processing space S. As a supporting gas, the O₂ gas serving as an oxidizing gas and the Ar gas for stabilizing the plasma are injected upward toward the central portion of the bottom surface of the ceiling plate 88 from the gas injection hole 124A of the supporting gas nozzle unit 124 constituting a part of the gas introduction mechanism 54 and they are diffused into the processing space S.

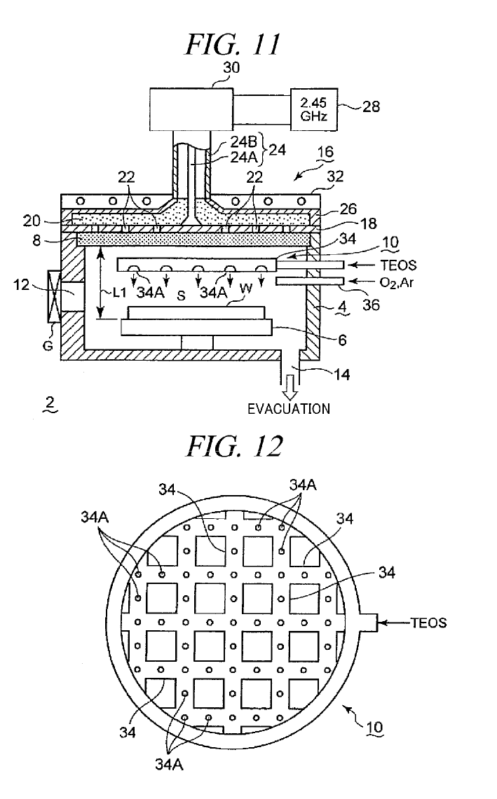

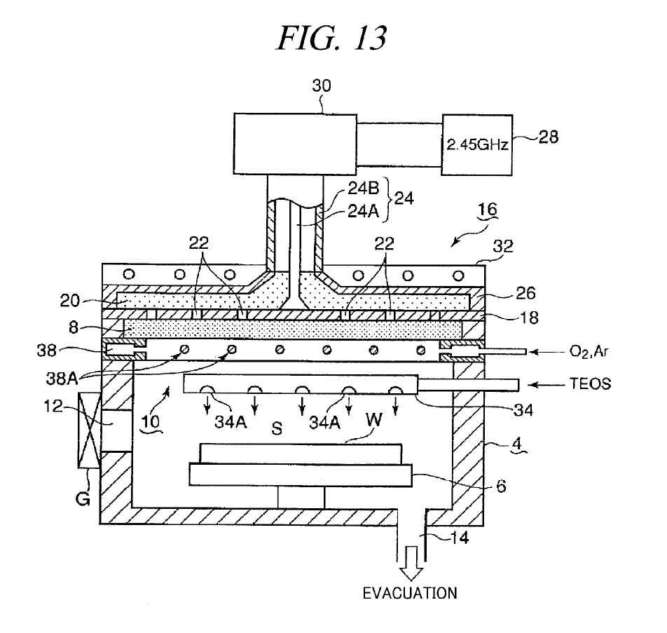

Further, the TEOS and the O₂ gas are activated by the plasma generated by the microwaves in the processing chamber 44, so that the reactions of these gases are accelerated, and a silicon oxide film is deposited on the surface of the wafer W by the plasma CVD. In this case, in the conventional plasma film forming apparatus illustrated in FIGS. 11 to 13, since the shower head unit 34 of the gas introduction mechanism 10 for supplying the TEOS is formed in the lattice shape, it is possible to uniformly provide the source gas to the processing space S. However, since this lattice-shaped shower head unit 34 occupying a large area also has a function of shielding the plasma, there occurs a problem that the plasma is shielded excessively, resulting in reduction of the electron density of the plasma and the film forming rate.

On the contrary, in the present embodiment, the central gas nozzle unit 112 and the peripheral gas nozzle unit 114 occupying small areas as possible are installed above the central portion Wa and the peripheral portion Wb of the wafer W, respectively, and the source gas is injected and supplied from each of the central gas injection holes 112A and the peripheral gas injection holes 114A provided in the nozzle units 112 and 114, respectively. Accordingly, the source gas having a very small flow rate in comparison to that of the supporting gas can be dispersed into the processing space S as uniformly as possible, and it is also possible to use the generated plasma as efficiently as possible by minimizing the areas occupied by the nozzle units 112 and 114 having the function of shielding the plasma. Further, by installing, for example, the plasma shielding member 130 including the inner and outer ring members 130A and 130B at the intermediate circumferential portion Wc of the wafer W where the film thickness tends to be thick, the plasma can be partially or selectively shielded, so that a film forming reaction at this portion is suppressed. As a result, the electron density of the plasma increases, so that it is possible to maintain a high film forming rate. Further, it is also possible to perform the formation of a SiO₂ film under a condition that the in-plane uniformity of film thickness is maintained high.

That is, the central gas injection holes 112A formed in the central gas nozzle unit 112 are positioned above the central portion Wa of the wafer W; the peripheral gas injection holes 114A formed in the peripheral gas nozzle unit 114 are positioned above the peripheral portion Wb of the wafer W; and the plasma shielding member 130 is installed above the intermediate circumferential portion Wc along its circumferential direction, so that the plasma is shielded at the plasma shielding member 130′ s portion. Therefore, it is possible to minimize the area occupied by the gas introduction mechanism 54 having the plasma shielding function, and it is also possible to suppress the plasma at the intermediate circumferential portion Wc of the wafer W where the film thickness tends to become thicker in comparison to the other wafer portions. As a result, the film forming rate and the in-plane uniformity of film thickness can be maintained high.

Furthermore, since the supporting gases, i.e., the O₂ gas and the Ar gas, are injected toward the central portion of the bottom surface of the ceiling plate 88, the source gas, i.e., the TEOS gas, can be prevented from making contact with the bottom surface of the ceiling plate 88 due to the presence of the supporting gas. Thus, an unnecessary thin film that may be a cause of particle can be prevented from being deposited on the bottom surface of the ceiling plate 88.

Here, process conditions for the plasma CVD are as follows. The process pressure is in the range of about 1.3 to 66 Pa, desirably in the range of about 8 Pa (50 mTorr) to 33 Pa (250 mTorr). The process temperature is in the range of about 250° C. to 450° C., e.g., about 390° C. The flow rate of the TEOS ranges from about 10 to 500 sccm, e.g., about 70 to 80 sccm. The flow rate of the O₂ is in the range of about 100 to 1000 sccm, e.g., about 900 sccm, which is higher than the flow rate of the TEOS. The flow rate of the Ar is in the range of about 50 to 500 sccm, for example, about 100 to 300 sccm.

Hereinafter, various evaluations that have been conducted to derive the apparatus of the present invention will be explained.

### <Evaluation of an Effect of the Lattice-Shaped Shower Head Unit on a Film Forming Rate>

First, an experiment was conducted to see how a lattice-shaped shower head unit affects a film forming rate, and the evaluation result is provided below.

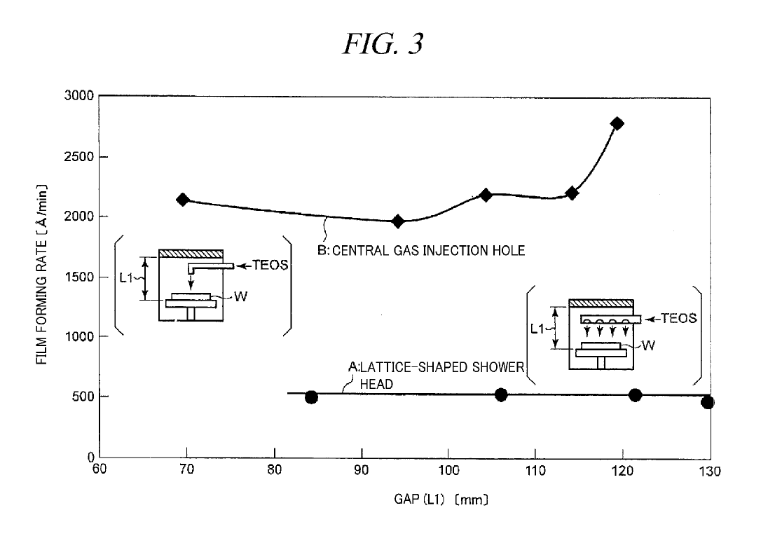

FIG. 3 is a graph for evaluating an effect of the lattice-shaped shower head unit on a film forming rate. The horizontal axis of FIG. 3 indicates a gap L1 between the wafer W and the ceiling plate 88 (see FIG. 11), and the vertical axis indicates the film forming rate. In FIG. 3, a curve A indicates an apparatus in which the lattice-shaped shower head unit is installed as the gas introduction mechanism 54, as illustrated in FIG. 11 and FIG. 12, and a curve B indicates an apparatus in which the leading end of a linear tube-shaped nozzle as the gas introduction mechanism 54 is inserted up to the central portion of the processing space and bent downward. The schematic configurations of both cases are shown in FIG. 3.

The process conditions for this experiment were as follows. The process pressure was in the range of about 50 to 250 mTorr; the process temperature was about 390° C.; the flow rates of TEOS, O₂ and Ar were set to be about 80 sccm, 900 sccm and 300 sccm, respectively. As can be seen from the curve A in FIG. 3, in case of supplying the TEOS by using the lattice-shaped shower head unit, a film forming rate is maintained constant regardless of the size of gap, and, also, in-plane uniformity of film thickness is good, though not shown in the graph. In this case, however, there is a drawback in that the film forming rate is low at about 500 Å/min because the lattice-shaped shower head unit occupying the large area has a plasma shielding function, resulting in reduction of electron density of the plasma and resultant degradation of film formation.

Meanwhile, as indicated by the curve B, in case of supplying the TEOS from one point in the central portion of the processing space, an overall film forming rate is very high at about 2000 Å/min though it is varied depending on the gap. That is, a film forming rate approximately four times as high as that of the curve A can be obtained. In case of the curve B, however, in-plane uniformity of film thickness is greatly deteriorated. As can be seen from the comparison of the two curves A and B, the film forming rate is greatly reduced in case of using the lattice-shaped shower head unit.

As a solution to this problem, the present invention employs a configuration in which the area occupied by the gas introduction mechanism is minimized to maintain a high film forming rate, and the gas injection holes 112A and 114A are provided above the central portion Wa and the peripheral portion Wb of the wafer W, respectively, so as to uniformly distribute the TEOS gas into the processing space.

### <Evaluation of the Plasma Shielding Member>

However, in the above-described configuration of the gas introduction mechanism in which the gas injection holes 112A and 114A are installed above the central portion Wa and the peripheral portion Wb of the wafer W, the in-plane uniformity of film thickness is deteriorated though the film forming rate can be kept high. In the present embodiment, to solve this problem, the plasma shielding member 130 occupying a sufficiently small area so as not to cause an excessive decrease of the film forming rate is installed to correspond to a portion where the film thickness tends to increase.

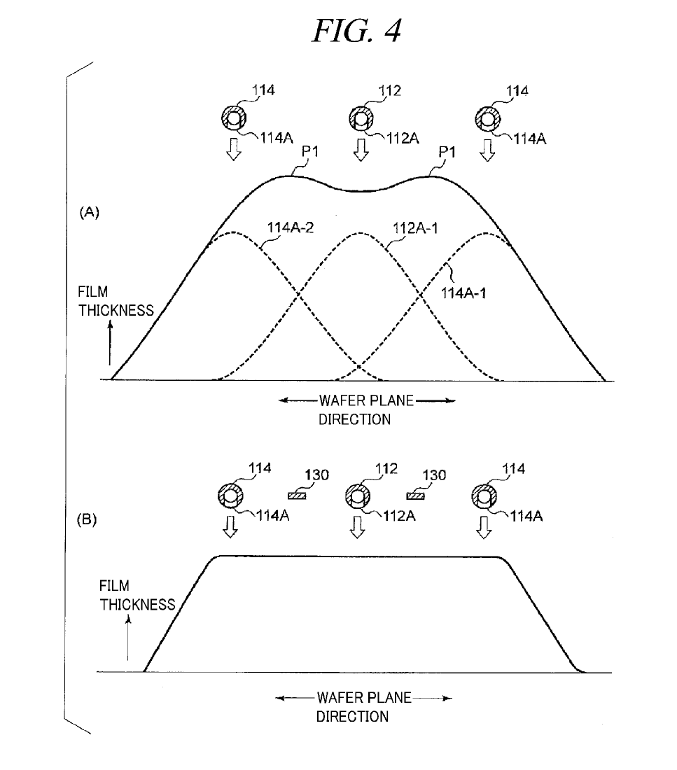

FIG. 4 presents schematic diagrams showing a relationship between a position of each gas injection hole and a film thickness along a cross-sectional direction of the wafer so as to explain how the plasma shielding member contributes to the improvement of the in-plane uniformity of film thickness. FIG. 4(A) shows a relationship between the gas injection holes and the film thickness in case that the central gas injection holes 112A and the peripheral gas injection holes 114A are installed while no plasma shielding member is provided; and FIG. 4(B) shows a relationship between the gas injection holes, the plasma shielding member and the film thickness in case that the central gas injection holes 112A, the peripheral gas injection holes 114A and the plasma shielding member 130 are installed (which corresponds to the apparatus of the present invention). In the drawing, only one central gas injection hole 112A is shown and the plasma shielding member 130 is shown as a single ring member for the purpose of simplicity of illustration.

In FIG. 4(A), a dashed-line curve 112A-1 indicates distribution of the thickness of a film formed by the TEOS injected from the central gas injection holes 112A; and a dashed-line curve 114A-1 indicates distribution of the thickness of a film formed by the TEOS injected from the peripheral gas injection hole 114A on the right side of the drawing; and a dashed-line curve 114A-2 indicates distribution of the thickness of a film formed by the TEOS injected from the peripheral gas injection hole 114A on the left side of the drawing.

Further, a solid-line curve in the drawing indicates an overall film thickness which is obtained by combining the dashed-line curves 112A-1, 114A-1 and 114A-2. As illustrated in FIG. 4(A), in case that only the central gas injection holes 112A and the peripheral gas injection holes 114A are installed without the plasma shielding member 130, though the film forming rate (film thickness) may be greatly increased, there is found a film thickness's peak which is protruded upward as indicated by an area P1 at the intermediate circumferential portion Wc of the wafer W corresponding to the portion between the central gas injection holes 112A and the peripheral gas injection holes 114A. As a result, the in-plane uniformity of film thickness becomes deteriorated.

Here, as illustrated in FIG. 4(B), the plasma shielding member 130 occupying a small area is installed at a position corresponding to the area P1, i.e., above a position where the thickness of the thin film is maximum. In this case, the film forming rate (film thickness) slightly decreases in the area P1 of FIG. 4(A) by the shielding of the plasma. As a result, it can be seen that the in-plane uniformity of film thickness is improved and maintained high while keeping a high film forming rate.

In a practical film forming apparatus, since the position of the area P1 is changed according to a supply amount of each gas, a process pressure, or the like, it is desirable to adjust the installation position of the plasma shielding member 130 depending on it. In this case, as stated above, the plasma shielding member 130 may be a single ring member, or may be made up of two ring members 130A and 130B arranged in a concentric shape. Further, since there is no specific limitation in the configuration of the plasma shielding member 130, it can be made up of three or more concentrically arranged ring members.

That is, the overall area occupied by the plasma shielding member 130, the number of the plasma shielding member 130, the thickness thereof and so forth are set so as to maintain the high in-plane uniformity of film thickness within the range that does not cause excessive reduction of the film forming rate. Further, the position of the area P1 is not limited to a midway position between the central gas injection holes 112A and the peripheral gas injection holes 114A, but it can be closer to the inner side or closer to the outer side than the midway position. Therefore, the installation position of the plasma shielding member 130 may be set depending on the position of the area P1.

### <Simulation Result Showing an Effect of the Plasma Shielding Member>

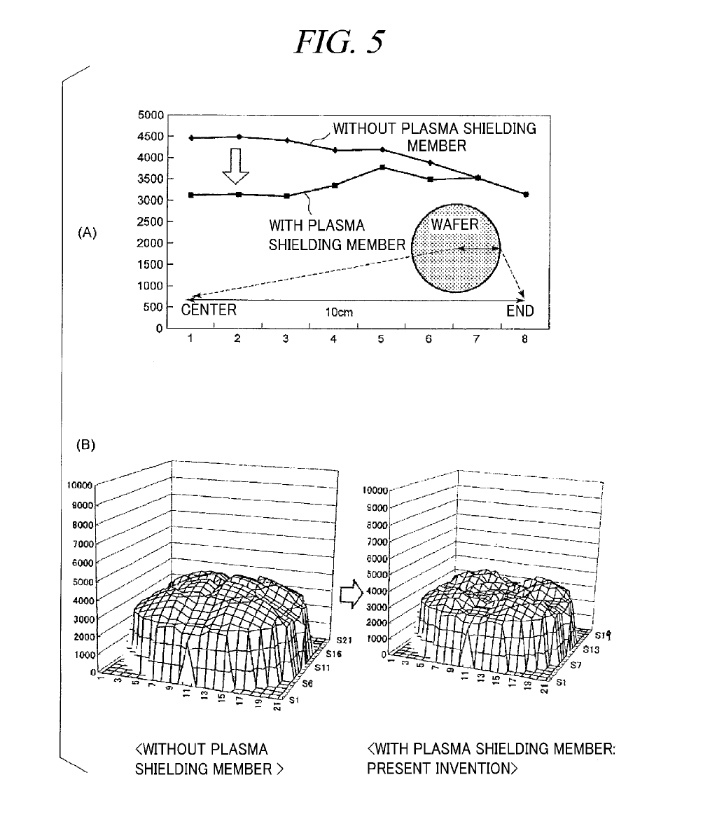

FIG. 5 is diagrams showing simulation results of film thickness distribution for explaining the effect of the plasma shielding member. FIG. 5(A) is a graph showing a variation of a mean value of film thickness measured from the center of the wafer to the edge thereof. The graph on the left side of FIG. 5(B) is a graph showing a three-dimensional film thickness distribution in case that the gas injection holes for TEOS are installed in the central portion and the peripheral portion of the processing space without installing the plasma shielding member (which corresponds to the film forming apparatus when the curve of FIG. 4(A) is obtained); and the graph on the right side of FIG. 5(B) is a graph showing a three-dimensional film thickness distribution of the apparatus of the present invention including the plasma shielding member (which corresponds to the film forming apparatus when the curve of FIG. 4(B) is obtained). Here, the wafer having a diameter of about 200 mm was used, and process conditions were as follows: the flow rates of O₂ gas, Ar gas and TEOS gas were about 325 sccm, 50 sccm and about 78 sccm, respectively; the pressure was about 90 mTorr; the temperature was about 390° C.; and the process time was about 60 sec.

As illustrated in the graph on the left side of FIG. 5(B), in case that the plasma shielding member is not installed, though a film forming rate (film thickness) is high, the degree of irregularities of the film thickness of the top surface is high. As a result, in-plane uniformity of film thickness is deteriorated. Meanwhile, as illustrated in the graph on the right side of FIG. 5(B), in the case of the apparatus of the present invention having the plasma shielding member installed therein, the film forming rate (film thickness) is high, and the degree of irregularities of film thickness of the top surface is lowered in comparison with the case shown in the graph on the left side of FIG. 5(B), so that the in-plane uniformity of film thickness can be improved. This can also be seen from the graph of FIG. 5(A), and in case of the present invention having the plasma shielding member installed therein, the in-plane uniformity of film thickness is greatly improved in comparison with the apparatus without installing the plasma shielding member therein.

### <Evaluation Upon an Actual Oxidation Process>

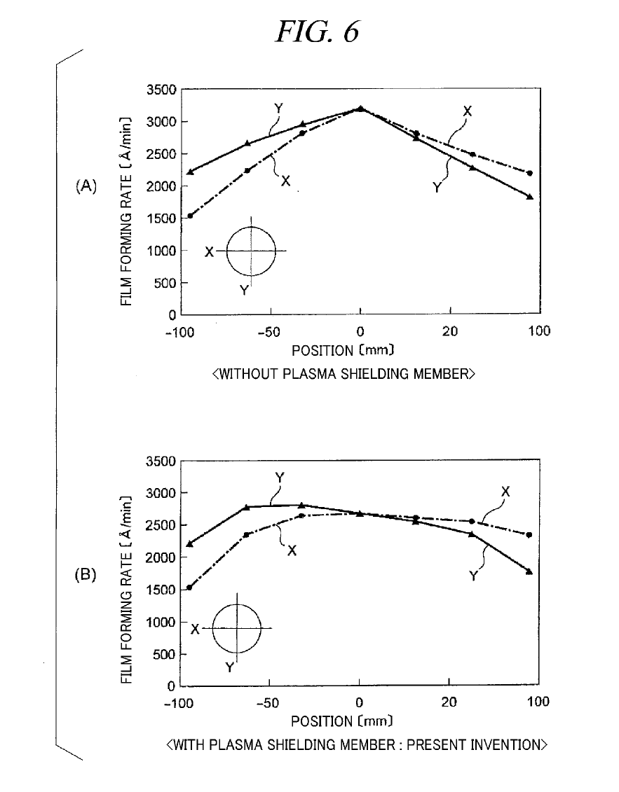

Hereinafter, a film formation of a SiO₂ film was actually performed by using the apparatus of the present invention, and the evaluation result is provided below. FIG. 6 provides graphs showing a relationship between a position along a diametric direction of the wafer and a film forming rate. FIG. 6(A) is a graph showing a film thickness distribution in case that only gas injection holes for TEOS are installed in the central portion and the peripheral portion of the processing space without installing plasma shielding member (which corresponds to the film forming apparatus when the curve of FIG. 4(A) is obtained); and FIG. 6(B) is a graph showing a film thickness distribution in case of the apparatus of the present invention having the plasma shielding member installed therein (which corresponds to the film forming apparatus when the curve of FIG. 4(B) is obtained).

Here, the wafer having a diameter of about 200 mm used and process conditions were as follows: the flow rates of O₂ gas, Ar gas and TEOS gas were set to be about 325 sccm, 50 sccm and 78 sccm, respectively; the pressure was about 90 mTorr; the temperature was about 390° C.; and the process time was about 60 sec. Further, in this experiment, measurement of the film thickness was conducted in orthogonal directions (X and Y directions) of the wafer.

As illustrated in FIG. 6(A), in case that the plasma shielding member is not installed, a film forming rate reaches a very high peak at the central portion and it decreases as it goes toward the peripheral portion. Meanwhile, as for the apparatus of the present invention with the plasma shielding member installed therein shown in FIG. 6(B), the film forming rate is substantially uniform at the central portion while it is slightly decreased at the peripheral portion, so that the in-plane uniformity of film thickness can be improved greatly as a whole.

### Second Embodiment

Hereinafter, a second embodiment of a plasma processing apparatus in accordance with the present invention will be explained. In the first embodiment using the apparatus illustrated in FIG. 1, the in-plane uniformity of film thickness can be improved to some extent while maintaining a high film forming rate. However, it is desirable to further improve the in-plane uniformity of film thickness. In the above-stated first embodiment, the supporting gas injection hole 124A of the supporting gas nozzle unit 124 is installed at the central portion, and the O₂ gas is supplied from this hole. In order to improve the in-plane uniformity of film thickness, however, it is necessary to provide a shower head structure which uniformly supplies the O₂ gas throughout the processing space S without blocking microwaves. In the second embodiment, a ceiling plate 88 constituting the ceiling portion of a processing chamber has a shower head function.

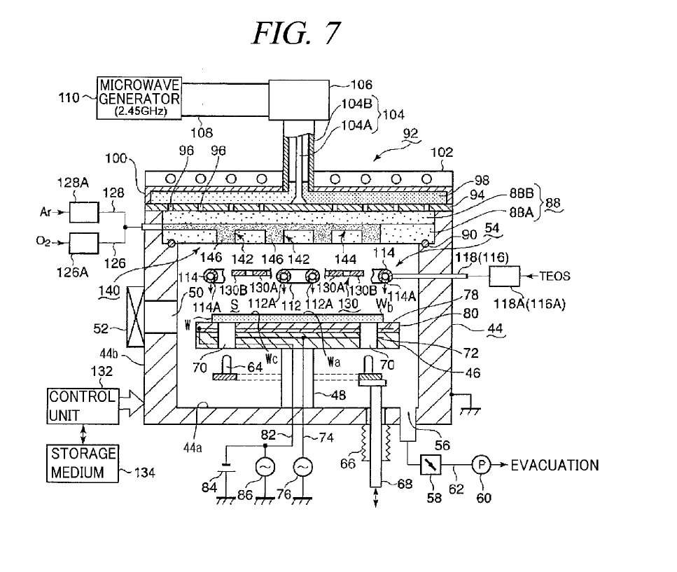

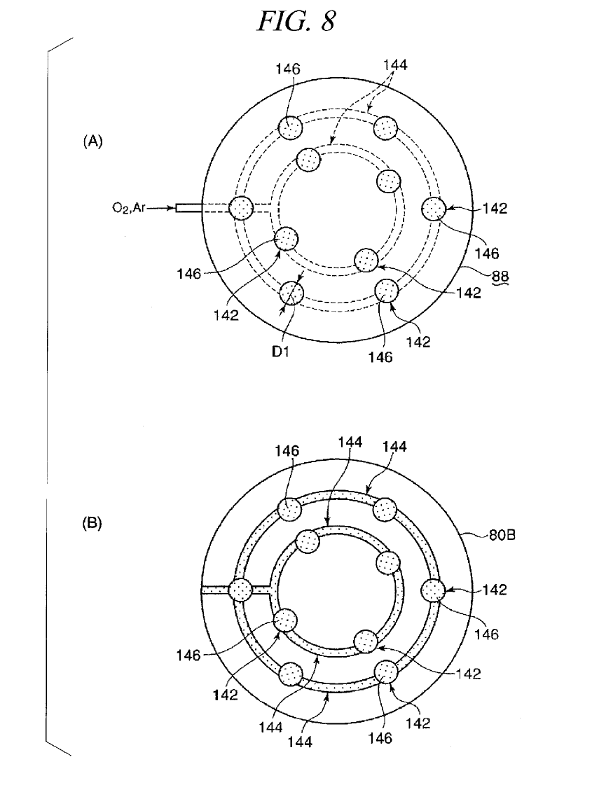

FIG. 7 is a schematic configuration view of the second embodiment of the film forming apparatus in accordance with the present invention; and FIG. 8 provides plane views showing a ceiling plate portion of the second embodiment. More particularly, FIG. 8(A) is a bottom view and FIG. 8(B) is a top view of a lower side ceiling plate member to be described later. Further, parts identical with those described in FIGS. 1 and 2 will be assigned like reference numerals, and redundant explanation thereof will be omitted.

As illustrated in FIG. 7, instead of the supporting gas nozzle unit 124 constituting a part of the gas introduction mechanism 54 in FIG. 1, a supporting gas supply unit 140 is formed at the ceiling plate 88 which divides the ceiling of a processing chamber 44. To be specific, as stated above, the ceiling plate 88 is made of a dielectric material, for example, quartz or ceramic such as alumina or aluminum nitride and is formed of a microwave transmissive material.

Further, the supporting gas supply unit 140 is formed at the ceiling plate 88 and includes a plurality of supporting gas injection holes 142 opened downward toward a processing space S. These gas injection holes 142 do not pass through gas passages 144 in an upper direction, and they are connected with gas channels 126 and 128 for supplying a predetermined gas, i.e., O₂ or Ar to these gas injection holes 142 through the gas passages 144 formed within the ceiling plate 88, and they supply the predetermined gas, i.e., O₂ or Ar, while controlling its flow rate.

The plurality of gas injection holes 142, e.g., 10 in the illustrated example, is arranged concentrically on the substantially entire bottom surface of the ceiling plate 88. Further, the plurality of gas passages 144, e.g., 2 in the illustrated example, is provided concentrically, corresponding to the arrangement of the gas injection holes 142, and they are communicated with each other. Furthermore, the gas passages 144 are configured to communicate with the upper end portions of the gas injection holes 142 so as to transfer the gas such as the O₂ gas or the like. Besides, the number of the gas injection holes 142 is not limited to 10 and it can be less or more than 10. In addition, the arrangement of the gas injection holes 142 is not limited to 2 rows and it can be 1 row or 3 rows or more. With this configuration, the ceiling plate 88 has a so-called shower head structure.

Further, each of the gas injection holes 142 and the gas passages 144 is filled with a porous dielectric material 146 made of a porous dielectric material having gas permeable property. By filling the gas injection holes 142 and the gas passages 144 with the porous dielectric material 146, the predetermined gas, i.e., the O₂ or Ar gas is allowed to flow therethrough while suppressing the occurrence of an abnormal discharge caused by microwaves.

Hereinafter, the dimension of each component will be described. A diameter D1 of the gas injection hole 142 is set to be equal to or less than one half of the wavelength λ₀ of an electromagnetic wave (microwave) which propagates to the ceiling plate 88, and, for example, it is set to be in the range of about 1 to 35 mm. If the diameter D1 is larger than one half of the wavelength λ₀, a dielectric constant at a place of the gas injection hole 142 would be changed greatly. As a result, an electric field density at this place would cause a big difference in plasma density distribution in comparison to other places, and this is not desirable.

Further, the diameter of a pore included in the porous dielectric material 146 is set to be about 0.1 mm or less. If the diameter of the pore is larger than 0.1 mm, there is a high likelihood that an abnormal discharge of plasma may be caused by the microwaves. Besides, in the porous dielectric material 146, numberless pores are connected with each other, so that the gas permeable property can be obtained. Furthermore, the diameter of each gas passage 144 is set to be as small as possible within a range in which a gas flow is not impeded, and the diameter of each gas passage 144 is set to be at least smaller than the diameter D1 of the gas injection hole 142 in order not to deteriorate the distribution of the electric field or the microwaves.

Hereinafter, an example manufacturing method of the ceiling plate 88 made of quartz will be explained briefly. The ceiling plate 88 is vertically divided into two parts: a lower ceiling plate member 88A and an upper ceiling plate member 88B bonded to the lower ceiling plate member 88A. First, the gas injection holes 142 are formed in predetermined positions of a circular plate-shaped quartz substrate having a predetermined thickness, which is a base material of the lower ceiling plate member 88A, and each of the gas passages 144 is provided by forming grooves at the surface of the quartz substrate.

Thereafter, the porous dielectric material 146 made of fused porous quartz having pores is introduced into each of the gas injection holes 142 and each of the gas passages 144, and then the entire surface of the substrate is polished and planarized, so that the lower ceiling plate member 88A is manufactured. Subsequently, the lower ceiling plate member 88A is bonded to the upper ceiling plate member 88B made of a circular plate-shaped quartz substrate which is planarized separately from the lower ceiling plate member 88A, and they are bonded to each other by heating or performing a heat treatment at a temperature equal to or lower than a strain point of the quartz. In this manner, it is possible to manufacture the ceiling plate 88 in which the gas injection holes 142 and the gas passages 144 are filled with the porous dielectric material 146 having the gas permeable property. If there is a low likelihood of the abnormal discharge of plasma at the gas passages 144 or the gas injection holes 142, it may be possible to enlarge the diameter of the pore of the porous dielectric material 146 or omit it.

Further, in the present embodiment, though the concentrically arranged gas passages 144 are configured to communicate with each other, the configuration is not limited thereto. In order to accelerate the flow of the gas such as O₂ or the like in the gas passages 144, it may be possible to supply the gas individually and separately to each concentrically arranged gas passage 144 from the gas channels 126 and 128 through which an O₂ gas source or an Ar gas source passes.

In the second embodiment configured as described above, TEOS (if necessary, it may include a rare gas such as the Ar gas or the like) is supplied into the processing space S from central gas injection holes 112A of a central gas nozzle unit 112 and peripheral gas injection holes 114A of a peripheral gas nozzle unit 114 in the same manner as in the first embodiment.

Meanwhile, the O₂ gas or the Ar gas is supplied into the processing space S from each of the supporting gas injection holes 142 of the supporting gas supply unit 140 installed in the ceiling plate 88. In this case, since the supporting gas injection holes 142 are formed throughout the substantially entire surface of the ceiling plate 88, it is possible to supply the O₂ gas or the Ar gas in a substantially uniform manner throughout the processing space S, together with an effect of plasma shielding members 130A and 130B formed above a mounting table 46. Accordingly, the in-plane uniformity of film thickness of a silicon oxide film formed on the wafer W can be further improved in comparison with the above-stated first embodiment.

Further, since the plasma generated by the RLSA is so-called surface wave plasma and is formed directly under the ceiling plate 88 at a distance of about several millimeters away from the ceiling plate 88, the O₂ gas or the Ar gas supplied from the gas injection holes 142 is immediately dissociated directly under the ceiling plate 88, whereby it becomes possible to maintain a high film forming rate, like in the first embodiment. Further, the process conditions, such as the process pressure, the process temperature, the supply amount of each gas are the same as those in the first embodiment.

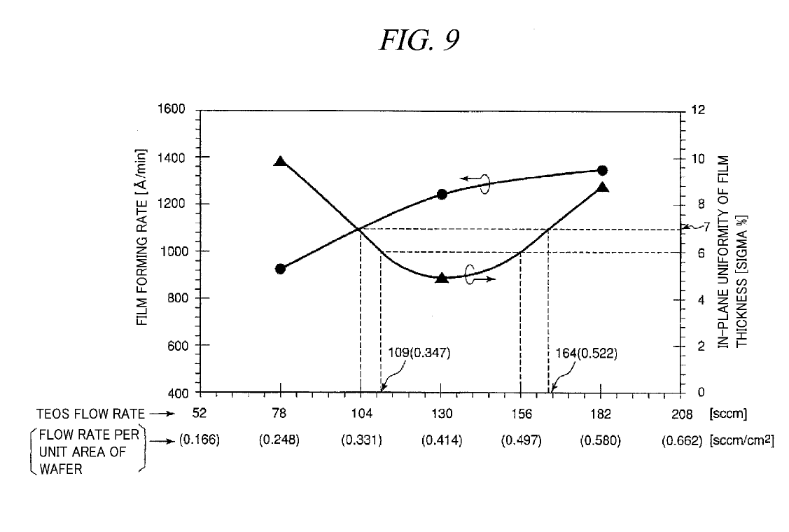

By using the plasma film forming apparatus in accordance with the second embodiment, a thin film was actually formed, and there was conducted an evaluation of a film forming rate and an in-plane uniformity of film thickness, and thus the evaluation result will be explained hereinafter. FIG. 9 is a graph showing dependency of the film forming rate and the in-plane uniformity of film thickness upon a flow rate of TEOS. The process conditions in this experiment were as follows: the process pressure was about 270 mTorr; the process temperature was about 390° C.; the flows rates of O₂ and Ar were set to be about 500 sccm and 50 sccm, respectively. A silicon wafer having a diameter of about 200 mm was used in this film forming process. Further, on the horizontal axis of the graph, a TEOS flow rate per unit area of the wafer is also specified. In this case, the TEOS flow rate is varied from about 78 sccm to 182 sccm.

As illustrated in FIG. 9, the film forming rate gradually increases in a gentle curve shape as the TEOS flow rate increases from about 78 sccm to 182 sccm. Meanwhile, the in-plane uniformity of film thickness decreases at the beginning with the increase of the TEOS flow rate, and it reaches a bottom (lowest point) when the TEOS flow rate is about 130 sccm but it increases afterward, so that it is represented by a characteristic curve having a downwardly protruded shape as a whole. Accordingly, if a tolerance range of the in-plane uniformity of film thickness is set to be about 7 [sigma %] or less, the TEOS flow rate is in the range of about 104 to 164 sccm, i.e., in the range of about 0.331 to 0.522 sccm/cm² when calculated in terms of the flow rate per unit area of the wafer. Desirably, if the tolerance range is set to be about 6% or less, the TEOS flow rate is in the range of about 109 to 156 sccm, i.e., in the range of about 0.347 to 0.497 sccm/cm² when calculated in terms of the flow rate per unit area of the wafer.

The in-plane uniformity of film thickness obtained from the film thickness distribution of the first embodiment shown in FIG. 5 is about 18 [sigma %], whereas the in-plane uniformity of film thickness can be easily achieved to be about 7 [sigma %] or less in the second embodiment. Therefore, it can be seen that the in-plane uniformity of film thickness can be further improved in the second embodiment in comparison with the first embodiment.

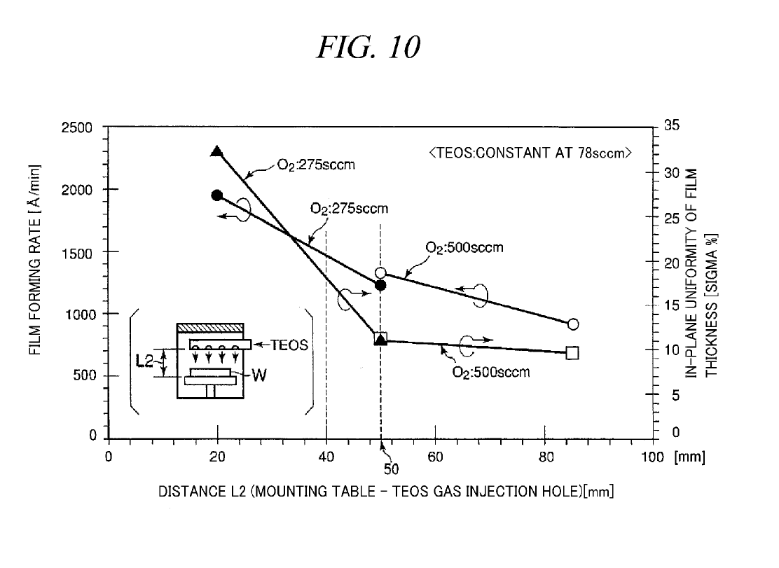

With respect to the second embodiment of the plasma film forming apparatus, a thin film was actually formed, and an optimum distance between the mounting table and the gas injection nozzles for TEOS was examined. Hereinafter, the examination result will be explained. FIG. 10 is a graph showing dependency of a film forming rate and an in-plane uniformity of film thickness upon a distance L2 between the mounting table and the horizontal level on which the gas injection nozzles for TEOS are positioned. In FIG. 10, a schematic diagram showing the distance L2 is also provided.

In this experiment, the process conditions were as follows: the process pressure was in the range of about 120 to 140 mTorr; the process temperature was about 390° C.; the flow rates of TEOS and Ar were set to be about 78 sccm and sccm, respectively. Further, the experiment was conducted for the two cases where the flow rates of O₂ were 275 sccm and 500 sccm, respectively. Here, the distance L2 was varied from about 20 to 85 mm. When the distance L2 was in the range of about 20 to 50 mm, the O₂ flow rate was set to be about 275 sccm; and if the distance L2 was in the range of about 50 to 85 mm, the O₂ flow rate was set to be about 500 sccm.

As illustrated in FIG. 10, as the distance L2 is varied from about 20 to 85 mm, the film forming rate gradually decreases and it is hardly affected by the flow rate of the O₂ gas.

Further, as the distance L2 is varied from about 20 to 85 mm, the in-plane uniformity of film thickness sharply increases in the distance range of about 20 to 50 mm, and in the distance range of about 50 to 85 mm, the in-plane uniformity of film thickness almost reaches its saturation level and is maintained substantially constant at about 10 [sigma %]. Further, also in this case, it is hardly affected by the flow rate of the O₂ gas.

Accordingly, in consideration of the film forming rate and the in-plane uniformity of film thickness, it is necessary to set the lower limit of the distance L2 to be about 40 mm, which is a point immediately before the in-plane uniformity of film thickness is saturated, so that the distance L2 needs to be about 40 mm or more, and desirably, mm or more. However, if the distance L2 increases excessively, the film forming rate may be extremely decreased. Therefore, the upper limit of the distance L2 is about 85 mm.

Furthermore, in the above-stated embodiments, the plasma shielding member 130 is made of quartz, but it is not limited thereto. That is, the plasma shielding member 130 can be made of any one material selected from a group consisting of quartz, ceramic, aluminum and semiconductor. In this case, it may be possible to use, e.g., AlN, Al₂O₂ or the like as the ceramic and to use, e.g., silicon, germanium or the like as the semiconductor. Besides, though the Ar gas is used as the supporting gas for stabilizing the plasma in the present embodiments, it is not limited thereto and it may be also possible to use other rare gases such as He, Ne, Xe or the like.

Further, in the present embodiments, the O₂ gas serving as an oxidizing gas or the Ar gas is supplied from the gas injection hole 124A provided directly under the center portion of the bottom surface of the ceiling plate 88 or supplied through the ceiling plate 88 configured as the shower head structure. However, since the supply amount of these gases is very high in comparison with that of the TEOS gas, they are not unevenly distributed within the processing chamber 44 but rapidly and easily diffused throughout the entire region of the processing space S. Therefore, it may be possible to install the gas injection hole 124A in the vicinity of the inner sidewall of the chamber.

Further, in the present embodiments, the TEOS is used as the source gas and the O₂ gas is used as the oxidizing gas in order to form the SiO₂ film by the plasma CVD. However, there is no specific limitation in the kind of the gases. Therefore, it may be possible to use SiH₄ or Si₂H₆ as the source gas, and NO, NO₂, N₂O or O₃ as the oxidizing gas.

Furthermore, though the present embodiments have been described for the example case of forming the SiO₂ film, they are not limited thereto. That is, the present invention can be applied to the formation of other kinds of thin films such as a SiN film, a CF film and the like. In addition, the target object to be processed is not limited to the semiconductor wafer, but the present invention can be applied to a glass substrate, an LCD substrate, a ceramic substrate and the like.

1. A plasma film forming apparatus comprising:
a processing chamber which has its ceiling portion opened and is evacuable;
a mounting table installed in the processing chamber, for mounting thereon a target object to be processed;
a ceiling plate which is airtightly installed at an opening of the ceiling portion and is made of a dielectric material capable of transmitting a microwave;
a gas introduction mechanism for introducing a processing gas including a film formation source gas and a supporting gas into the processing chamber; and
a microwave introduction mechanism which is installed at a ceiling plate's side and has a planar antenna member so as to introduce the microwave into the processing chamber,
wherein the gas introduction mechanism includes:
a central gas injection hole for the source gas, located above a central portion of the target object;
a plurality of peripheral gas injection holes for the source gas, arranged above a peripheral portion of the target object along a circumferential direction of the target object; and
a plasma shielding member for shielding plasma is installed above an intermediate portion located between the central portion and the peripheral portion of the target object along the circumferential direction thereof.

2. The plasma film forming apparatus of claim 1, wherein the plasma shielding member is located above a position where a thin film formed on a surface of the target object becomes thicker when a film formation is performed without the plasma shielding member by injecting the source gas from the central gas injection hole and the peripheral gas injection holes.

3. The plasma film forming apparatus of claim 1, wherein the plasma shielding member includes one or more ring member.

4. The plasma film forming apparatus of claim 1, wherein the plasma shielding member is made of one material selected from a group consisting of quartz, ceramic, aluminum and semiconductor.

5. The plasma film forming apparatus of claim 1, wherein the gas introduction mechanism includes a central gas nozzle unit having the central gas injection hole and a peripheral gas nozzle unit having the peripheral gas injection holes.

6. The plasma film forming apparatus of claim 5, wherein both the central gas nozzle unit and the peripheral gas nozzle unit have a ring shape.

7. The plasma film forming apparatus of claim 5, wherein the central gas nozzle unit and the peripheral gas nozzle unit are configured such that their gas flow rates are individually controlled.

8. The plasma film forming apparatus of claim 1, wherein the gas introduction mechanism includes a supporting gas nozzle unit for introducing the supporting gas.

9. The plasma film forming apparatus of claim 8, wherein the supporting gas nozzle unit has a gas injection hole for the supporting gas, which injects the gas toward the ceiling plate from a position directly under a central portion of the ceiling plate.

10. The plasma film forming apparatus of claim 1, wherein the gas introduction mechanism includes a supporting gas supply unit installed at the ceiling plate so as to introduce the supporting gas.

11. The plasma film forming apparatus of claim 10, wherein the supporting gas supply unit has a gas passage for the supporting gas installed at the ceiling plate, and a plurality of gas injection holes for the supporting gas installed at a bottom surface of the ceiling plate so as to communicate with the gas passage.

12. The plasma film forming apparatus of claim 11, wherein the gas injection holes for the supporting gas are distributed throughout the bottom surface of the ceiling plate.

13. The plasma film forming apparatus of claim 11, wherein the gas passage for the supporting gas and/or the gas injection holes for the supporting gas are filled with a porous dielectric material having a gas permeable property.

14. The plasma film forming apparatus of claim 10, wherein an introduction amount of the source gas is in a range of about 0.331 sccm/cm² to 0.522 sccm/cm².

15. The plasma film forming apparatus of claim 10, wherein the gas injection holes for the source gas are arranged on the same horizontal plane, and
a distance between the mounting table and the horizontal plane on which the gas injection holes for the source gas are located is set to be about 40 mm or more.

16. The plasma film forming apparatus of claim 1, wherein the mounting table has a heating unit for heating the target object.

17. The plasma film forming apparatus of claim 1, wherein the source gas includes one material selected from a group consisting of TEOS, SiH₄ and Si₂H₆, and
the supporting gas includes one material selected from a group consisting of O₂, NO, NO₂, N₂O and O₃.

18. A plasma film forming method comprising:
introducing a processing gas including a film formation source gas and a supporting gas into an evacuable processing chamber; and
generating plasma by introducing a microwave from a ceiling of the processing chamber and forming a thin film on a surface of a target object installed in the processing chamber,
wherein, when the processing gas is introduced into the processing chamber, the source gas is injected and introduced from above a central portion and a peripheral portion of the target object, and
the plasma is shielded by a plasma shielding member installed above the target object at a position between the central portion and the peripheral portion of the target object, so that the thin film is formed.
